(19) United States
(12) Patent Application Publication
(10) Pub. No.: US 2025/0372453 A1
(43) Pub. Date: Dec. 4, 2025

(54) TREATMENT METHOD FOR SHEET, MANUFACTURING METHOD FOR CHIP, AND MANUFACTURING METHOD FOR SUBSTRATE

(71) Applicant: DISCO CORPORATION, Tokyo (JP)

(72) Inventor: Yoshinobu SAITO, Tokyo (JP)

(21) Appl. No.: 19/191,175

(22) Filed: Apr. 28, 2025

(30) Foreign Application Priority Data
May 28, 2024 (JP) 2024-085981
Dec. 9, 2024 (JP) 2024-214409

(51) Int. Cl. H01L 21/78; H01L 21/683

(52) U.S. Cl. CPC H01L 21/78; H01L 21/6836

(57) ABSTRACT

There is provided a treatment method for a sheet by which treatment for the sheet fixed to an object is executed. The treatment method includes preparing the object to which the sheet is fixed, forming a light absorbing film that absorbs light and generates heat on a non-fixed region that is not fixed to the object in the sheet, and heating and shrinking the non-fixed region by irradiating the light absorbing film with the light and causing the light absorbing film to generate heat.

### BACKGROUND OF THE INVENTION

### Field of the Invention

The present invention relates to a treatment method for a sheet by which treatment for the sheet fixed to an object is executed, a manufacturing method for a chip by which an object to which a sheet is fixed is divided to manufacture the chip, and a manufacturing method for a substrate by which an object to which a sheet is fixed is processed to manufacture the substrate.

### Description of the Related Art

In a manufacturing process for device chips, a wafer including a device region in which a plurality of devices are formed on a front surface side is used. The device region is segmented into a plurality of regions by planned dividing lines (streets) set in a lattice manner, and the device is formed in each of the plurality of regions. The device chips including the device are obtained by dividing this wafer along the planned dividing lines to dice the wafer into individual pieces. The device chips are incorporated in various pieces of electronic equipment, such as mobile phones and personal computers.

For the dividing of the wafer, a cutting apparatus that cuts the wafer by an annular cutting blade is used. Further, in recent years, development of a process of dividing a wafer by laser processing has also been advanced. For example, by irradiating a wafer with a laser beam, a modified layer that functions as an origin of dividing is formed inside the wafer along the planned dividing line. Thereafter, an external force is given to the wafer by pulling and expanding a sheet (holding tape) fixed to the wafer. As a result, the wafer breaks, with the modified layer being the origin, and is divided along the planned dividing line (refer to Japanese Patent Laid-open No. 2007-173475).

Moreover, in recent years, along with size reduction of electronic equipment, thickness reduction of device chips has been requested. Thus, processing of grinding and thinning a wafer before dividing is sometimes executed. However, if the whole of the wafer is thinned, the rigidity of the wafer lowers, and the possibility of occurrence of deformation or breakage of the wafer increases. This makes handling of the wafer after the thinning difficult. Thus, there has been proposed a processing method referred to as TAIKO grinding in which only a central portion overlapping with the device region in a back surface side of a wafer is ground and thinned. When the TAIKO grinding is executed, an outer circumferential portion of the wafer is not thinned but kept in a thick state although a recess portion is formed at the central portion of the wafer. As a result, the outer circumferential portion of the wafer functions as an annular reinforcing portion, and the lowering of the rigidity of the wafer after the grinding is suppressed (refer to Japanese Patent Laid-open No. 2007-19461).

### SUMMARY OF THE INVENTION

In executing treatment such as dividing or grinding for an object such as a wafer, the object is supported by an annular frame for convenience of handling (conveyance, holding, and the like) of the object. Specifically, a circular opening is made at a central portion of the frame, and the object is disposed inside the frame. Then, a sheet (film) such as an adhesive tape is fixed to the object and the frame in such a manner as to cover the opening. Thus, the object is supported by the frame through the sheet.

However, loosening sometimes occurs in the sheet when predetermined treatment is executed for the object in a state in which the sheet is fixed to the object. For example, when a process of giving an external force to a wafer by expansion of a sheet to divide the wafer is executed as described above, a state in which the sheet remains stretched is made after the dividing of the wafer, and loosening occurs in the sheet. Further, in order to decrease the possibility of occurrence of a collision between chips after a wafer is divided into a plurality of chips, treatment of expanding a sheet fixed to the wafer to widen the interval between device chips is sometimes executed. Also in this case, loosening similarly occurs in the sheet. Moreover, in treatment for a wafer for which the above-mentioned TAIKO grinding has been executed, a sheet is fixed in such a manner as to be pressed against the recess portion formed on the back surface side of the wafer. Then, after various kinds of treatment are executed for the wafer, finally the outer circumferential portion (reinforcing portion) is separated and removed from the wafer. At this time, tension of the sheet fixed to the recess portion of the wafer is released, and loosening sometimes occurs in the sheet.

If loosening occurs in the sheet, inconvenience is caused in subsequent handling of the object. For example, a state in which the object droops from the frame is made due to the loosening of the sheet, and it becomes difficult to house the object in a predetermined housing container (cassette) in some cases. Further, when an object that has been divided into a plurality of chips is supported by a loose sheet and is conveyed, there is a possibility that the chips collide with each other due to a swing of the object and the chip is damaged.

Thus, when loosening has occurred in a sheet due to treatment for an object, treatment of heating a region in which the loosening of the sheet has occurred (loosening region) to shrink the loosening region is sometimes executed. Specifically, the loosening region of the sheet is irradiated with light such as a laser beam, and the loosening region absorbs the light and is heated. Due to this, the loosening region shrinks and the loosening of the sheet is eliminated.

However, the material of the sheet fixed to the object differs depending on the kind of object, the contents of treatment executed for the object, and the like. In addition, in a case of irradiating the sheet with light to eliminate loosening of the sheet, the wavelength of the light is required to be set depending on the material of the sheet such that the light may be absorbed by the sheet at high efficiency. Thus, effort is required for the process of eliminating the loosening of the sheet by the irradiation with light, and the high-efficiency light absorption itself is difficult depending on the material of the sheet in some cases. Further, a facility capable of irradiating the sheet with light with various wavelengths is required to be prepared. This is a cause of increase in the complexity of the facility and increase in the cost.

The present invention is made in view of such a problem, and an object thereof is to provide a treatment method for a sheet, a manufacturing method for a chip, and a manufacturing method for a substrate that can easily suppress loosening of a sheet fixed to an object.

In accordance with an aspect of the present invention, there is provided a treatment method for a sheet by which treatment for the sheet fixed to an object is executed. The treatment method includes preparing the object to which the sheet is fixed, forming a light absorbing film that absorbs light and generates heat on a non-fixed region that is not fixed to the object in the sheet, and heating and shrinking the non-fixed region by irradiating the light absorbing film with the light and causing the light absorbing film to generate heat.

Preferably, the sheet is fixed to an annular frame having an opening in which the object is allowed to be disposed, and the non-fixed region is an annular region exposed between the object and the frame. Further, preferably, treatment for the object is executed, and the non-fixed region in which loosening has occurred due to the treatment for the object is shrunk.

Moreover, preferably, the treatment for the object is treatment of dividing the object along a planned dividing line by expanding the sheet after forming an origin of dividing in the object along the planned dividing line. Further, preferably, the object in which a recess portion is made at a central portion and an annular reinforcing portion that surrounds the recess portion is made at an outer circumferential portion and for which the sheet is fixed to the recess portion and the reinforcing portion is prepared, and the treatment for the object is treatment of separating the reinforcing portion from the object.

In accordance with another aspect of the present invention, there is provided a manufacturing method for a chip by which an object to which a sheet is fixed is divided to manufacture the chip. The manufacturing method includes preparing the object to which the sheet is fixed, dividing the object into a plurality of the chips along a planned dividing line by expanding the sheet after forming an origin of dividing in the object along the planned dividing line, forming a light absorbing film that absorbs light and generates heat on a non-fixed region that is not fixed to the object in the sheet, and heating and shrinking the non-fixed region by irradiating the light absorbing film with the light and causing the light absorbing film to generate heat.

In accordance with a further aspect of the present invention, there is provided a manufacturing method for a chip by which an object to which a sheet is fixed is divided to manufacture the chip. The manufacturing method includes preparing the object to which the sheet is fixed, widening an interval between a plurality of the chips by expanding the sheet after dividing the object into the plurality of the chips along a planned dividing line, forming a light absorbing film that absorbs light and generates heat on a non-fixed region that is not fixed to the object in the sheet, and heating and shrinking the non-fixed region by irradiating the light absorbing film with the light and causing the light absorbing film to generate heat.

In accordance with a still further aspect of the present invention, there is provided a manufacturing method for a substrate by which an object to which a sheet is fixed is processed to manufacture the substrate. The manufacturing method includes preparing the object in which a recess portion is made at a central portion and an annular reinforcing portion that surrounds the recess portion is made at an outer circumferential portion and for which the sheet is fixed to the recess portion and the reinforcing portion, separating the reinforcing portion from the object to manufacture the substrate, forming a light absorbing film that absorbs light and generates heat on a non-fixed region that is not fixed to the object in the sheet, and heating and shrinking the non-fixed region by irradiating the light absorbing film with the light and causing the light absorbing film to generate heat.

In the treatment method for a sheet, the manufacturing method for a chip, and the manufacturing method for a substrate according to the aspects of the present invention, the non-fixed region of the sheet is heated to be shrunk by irradiating the light absorbing film formed on the non-fixed region with the light and causing the light absorbing film to generate heat. Due to this, work of setting irradiation conditions of the light in detail depending on the material of the sheet becomes unnecessary, and treatment of suppressing loosening of the sheet is simplified.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a flowchart depicting a treatment method for a sheet;

FIG. 2 is a perspective view depicting an object, a frame, and a sheet;

FIG. 3 is a perspective view depicting a frame unit;

FIG. 4 is a partially sectional front view depicting a laser processing apparatus;

FIG. 5A is a partially sectional front view depicting an expanding apparatus;

FIG. 5B is a partially sectional front view depicting the expanding apparatus that expands the sheet;

FIG. 6 is a partially sectional front view depicting the expanding apparatus in a light absorbing film forming step;

FIG. 7 is a sectional view depicting part of the sheet and a light absorbing film;

FIG. 8 is a partially sectional front view depicting the expanding apparatus in a shrinking step;

FIG. 9A is a perspective view depicting a modification of the object;

FIG. 9B is a sectional view depicting a modification of the frame unit;

FIG. 10A is a partially sectional front view depicting a laser processing apparatus;

FIG. 10B is a sectional view depicting part of an object in which a modified region has been formed;

FIG. 11A is a partially sectional front view depicting a separating apparatus when an external force is given to the object;

FIG. 11B is a partially sectional front view depicting the separating apparatus when a reinforcing portion is separated from the object;

FIG. 12 is a partially sectional front view depicting the separating apparatus in the light absorbing film forming step;

FIG. 13 is a partially sectional front view depicting the separating apparatus in the shrinking step;

FIG. 14A is a sectional view depicting the object divided by cutting processing; and

FIG. 14B is a sectional view depicting the object divided by laser processing.

### DETAILED DESCRIPTION OF THE PREFERRED EMBODIMENTS

### First Embodiment

An embodiment according to an aspect of the present invention is described below with reference to the accompanying drawings. In the present embodiment, a description is given of a specific example of a treatment method for a sheet (treatment method for a film) according to the aspect of the present invention.

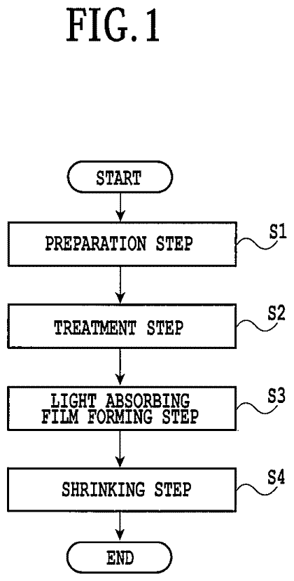

FIG. 1 is a flowchart depicting the treatment method for a sheet. In the present embodiment, after a preparation step S1 of preparing an object to which a sheet is fixed is executed, a treatment step S2 of executing predetermined treatment for the object is executed. Thereafter, loosening that has occurred in the sheet in the treatment step S2 is reduced or eliminated by executing a light absorbing film forming step S3 and a shrinking step S4.

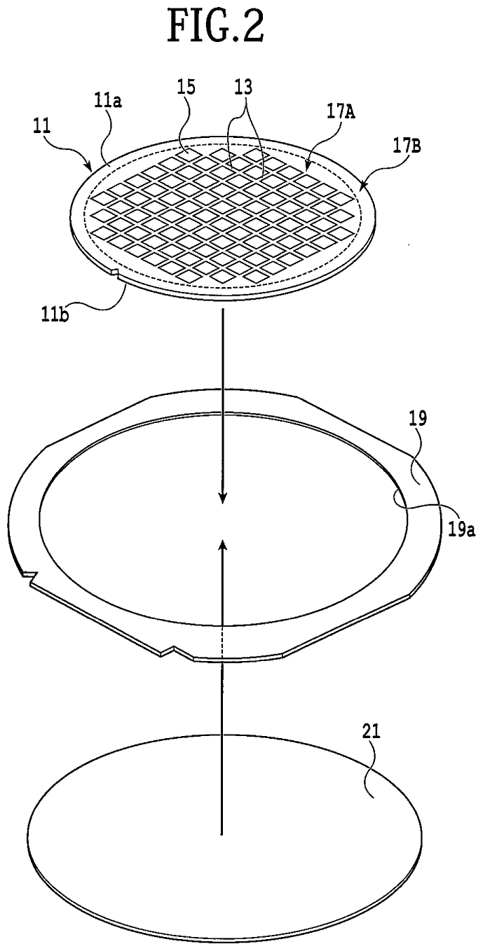

FIG. 2 is a perspective view depicting an object 11, a frame 19, and a sheet (film) 21. The object 11 is a component to which the sheet 21 is fixed, and corresponds to a treatment-target object (workpiece, cleaning-target object, inspection-target object, and the like) for which various kinds of treatment are executed by treatment apparatuses such as a processing apparatus, a cleaning apparatus, and an inspection apparatus.

For example, the object 11 is a circular disc-shaped wafer composed of a semiconductor material such as single-crystal silicon, and includes a front surface (first surface) 11a and a back surface (second surface) 11b substantially parallel to each other. Further, the object 11 is segmented into a plurality of rectangular regions by a plurality of planned dividing lines (streets) 13 arranged in a lattice manner to intersect each other. A device 15 such as an integrated circuit (IC), large scale integration (LSI), a light emitting diode (LED), or a micro electro mechanical systems (MEMS) device is formed on a side of the front surface 11a in each of the plurality of regions marked out by the planned dividing lines 13.

The object 11 includes, on the side of the front surface 11a, a substantially circular device region 17A in which the plurality of devices 15 are formed and an annular outer circumferential surplus region 17B that surrounds the device region 17A. The outer circumferential surplus region 17B corresponds to a band-shaped region that includes the outer circumferential edge of the front surface 11a and has a predetermined width (for example, approximately 2 mm). In the outer circumferential surplus region 17B, the device 15 is not formed or only a device (dummy device) that is not used for a product is formed. Note that, i0n FIG. 2, an imaginary boundary between the device region 17A and the outer circumferential surplus region 17B is depicted by a dashed line.

In the present embodiment, a description is given of a case in which dividing processing to divide the object 11 along the planned dividing lines 13 is executed. That is, the object 11 is a workpiece for which the dividing processing is executed. By dividing the object 11 along the planned dividing lines 13, a plurality of chips (device chips) each including the device 15 are obtained.

There is no limit on the kind, material, shape, structure, size, and the like of the object 11. For example, the object 11 may be a substrate (wafer) composed of a semiconductor other than silicon (GaAs, InP, GaN, SiC, or the like), sapphire, glass, ceramic, resin, metal, or the like. Further, there is no limit also on the kind, quantity, shape, structure, size, arrangement, and the like of the devices 15, and the device 15 does not have to be formed in the object 11. Moreover, the object 11 may be a package substrate such as a chip size package (CSP) substrate or a quad flat non-leaded package (QFN) substrate. For example, the package substrate is formed by mounting a plurality of device chips on a predetermined substrate and covering and sealing the mounted device chips by a resin layer (mold resin). By dividing the package substrate along predetermined planned dividing lines, a plurality of package devices each including a plurality of packaged device chips are manufactured.

In executing treatment for the object 11, the object 11 is supported by the annular frame 19 for convenience of handling (conveyance, holding, and the like) of the object 11. The frame 19 is composed of a metal such as stainless steel (SUS), and a circular opening 19a that penetrates the frame 19 in the thickness direction is made at a central portion of the frame 19. Note that the diameter of the opening 19a is larger than that of the object 11, and the object 11 can be disposed in the opening 19a.

The circular sheet 21 is fixed to the object 11 and the frame 19. The sheet 21 is a sheet (expanding sheet) that can be expanded by giving of an external force. For example, a tape including a circular base and an adhesive layer (glue layer) disposed on the base is used as the sheet 21. As the base, a resin such as polyolefin or polyvinyl chloride rich in expandability can be used. As the adhesive layer, an epoxy-based, acrylic-based, rubber-based adhesive, or the like can be used. Further, the adhesive layer may have a property that its adhesiveness to the object 11 lowers through execution of predetermined treatment. For example, the adhesive layer may be an ultraviolet-curable resin that cures through irradiation with ultraviolet.

In a state in which the object 11 is disposed inside the opening 19a, the sheet 21 is fixed to the object 11 and the frame 19 in such a manner as to cover the opening 19a. Specifically, a central portion of the sheet 21 is applied to the side of the back surface 11b of the object 11, and an outer circumferential portion of the sheet 21 is applied to the lower surface side of the frame 19. Thus, the object 11 is supported by the frame 19 through the sheet 21.

However, the sheet 21 may be a sheet (thermocompression bonding sheet) that can be thermocompression-bonded to the object 11 and the frame 19. The thermocompression bonding sheet is composed of a thermoplastic resin having a lower melting point than the object 11, and does not include an adhesive layer (glue layer). For example, as the thermocompression bonding sheet, an olefin-based sheet, a styrene-based sheet, a polyester-based sheet, or the like is used. A polyethylene sheet, a polypropylene sheet, and the like can be given as examples of the olefin-based sheet. A polystyrene sheet and the like can be given as examples of the styrene-based sheet. A polyethylene terephthalate sheet, a polyethylene naphthalate sheet, and the like can be given as examples of the polyester-based sheet.

In fixing the thermocompression bonding sheet to the object 11 and the frame 19, for example, a roller (heat roller) internally including a heat source is used. Specifically, while the heat roller heated to a predetermined temperature gets contact with the thermocompression bonding sheet and heats the thermocompression bonding sheet, the thermocompression bonding sheet is pressed against the object 11 and the frame 19. Thereby, the thermocompression bonding sheet softens and gets tight contact with the object 11 and the frame 19 to be thermocompression-bonded thereto.

The thermocompression bonding sheet is heated such that the temperature of the thermocompression bonding sheet becomes equal to or higher than the softening point of the thermocompression bonding sheet and equal to or lower than the melting point of the thermocompression bonding sheet. However, the thermocompression bonding sheet sometimes does not have a clear softening point. In this case, the thermocompression bonding sheet is heated such that the temperature of the thermocompression bonding sheet becomes equal to or higher than a temperature lower than the melting point of the thermocompression bonding sheet by a predetermined temperature (for example, 20° C.) and equal to or lower than the melting point of the thermocompression bonding sheet. For example, when the thermocompression bonding sheet is a polyethylene sheet, the heating temperature can be set to at least 120° C. and at most 140° C. When the thermocompression bonding sheet is a polypropylene sheet, the heating temperature can be set to at least 160° C. and at most 180° C. Further, when the thermocompression bonding sheet is a polystyrene sheet, the heating temperature can be set to at least 220° C. and at most 240° C. Moreover, when the thermocompression bonding sheet is a polyethylene terephthalate sheet, the heating temperature can be set to at least 250° C. and at most 270° C. When the thermocompression bonding sheet is a polyethylene naphthalate sheet, the heating temperature can be set to at least 160° C. and at most 180° C.

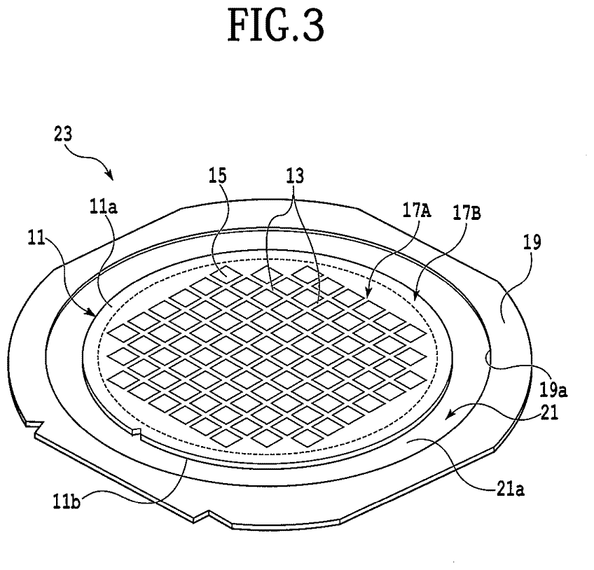

FIG. 3 is a perspective view depicting a frame unit (object unit) 23. Due to the support of the object 11 by the frame 19 through the sheet 21, the frame unit 23 including the object 11, the frame 19, and the sheet 21 is formed. Further, in a state in which the object 11 is supported by the frame 19, conveyance, holding, and the like of the object 11 are executed and predetermined treatment is executed for the object 11. However, the object 11 may be supported by a component other than the annular frame 19. That is, the sheet 21 does not necessarily have to be fixed to the frame 19.

The sheet 21 has a non-fixed region 21a as a region that is not fixed to the object 11. In the frame unit 23 in which the object 11 is supported by the frame 19 through the sheet 21, an annular region that is fixed to neither the object 11 nor the frame 19 and is exposed between the object 11 and the frame 19 corresponds to the non-fixed region 21a.

In the preparation step S1, the frame unit 23 is prepared, for example, according to the above-described procedure. Note that an executor of the treatment method for a sheet according to the present embodiment may form and prepare the frame unit 23 by oneself, or may prepare the frame unit 23 by obtaining the frame unit 23 formed by another person.

Next, the treatment step S2 of executing treatment for the object 11 is executed. In the present embodiment, a description is given of a case in which dividing processing is executed for the object 11 in the treatment step S2 and the object 11 is divided into a plurality of chips. For example, the treatment step S2 includes a step of forming an origin of dividing in the object 11 (origin-of-dividing forming step) and a step of giving an external force to the object 11 (external force giving step).

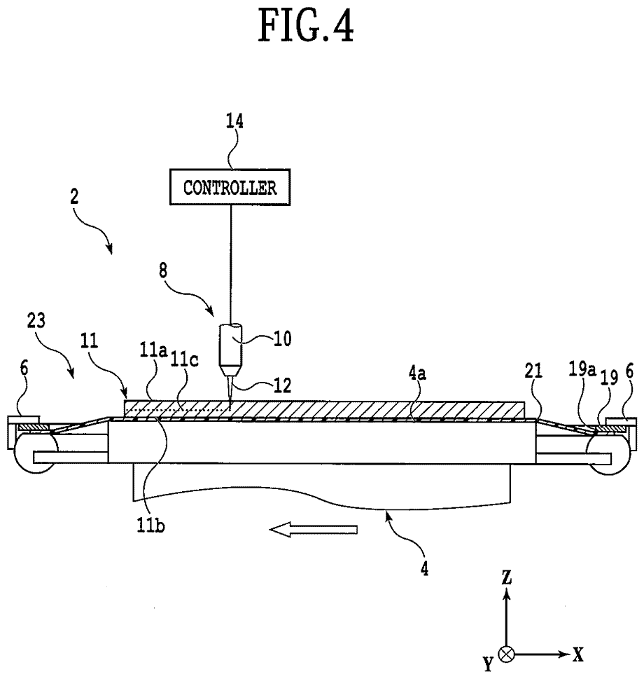

FIG. 4 is a partially sectional front view depicting a laser processing apparatus 2. For example, in the origin-of-dividing forming step, a modified layer that functions as the origin of dividing is formed inside the object 11 by executing laser processing for the object 11 by the laser processing apparatus 2. Note that, in FIG. 4, an X-axis direction (processing feed direction, first horizontal direction) and a Y-axis direction (indexing feed direction, second horizontal direction) are directions perpendicular to each other. Moreover, a Z-axis direction (upward-downward direction, height direction, vertical direction) is the direction perpendicular to the X-axis direction and the Y-axis direction.

The laser processing apparatus 2 includes a chuck table (holding table) 4 that holds the object 11. The upper surface of the chuck table 4 is a circular flat surface substantially parallel to a horizontal plane (XY-plane), and forms a holding surface 4a that holds the object 11. The holding surface 4a is connected to a suction source (not depicted) such as an ejector through a flow path (not depicted) formed inside the chuck table 4, a valve (not depicted), and the like.

A movement mechanism (not depicted) of a ball screw system that moves the chuck table 4 along the X-axis direction and the Y-axis direction is coupled to the chuck table 4. Further, a rotational drive source (not depicted) such as a motor that rotates the chuck table 4 around a rotation axis substantially perpendicular to the holding surface 4a is coupled to the chuck table 4. Moreover, a plurality of clamps 6 that grasp and fix the frame 19 that supports the object 11 are disposed around the chuck table 4.

Further, the laser processing apparatus 2 includes a laser irradiation unit 8 that executes irradiation with a laser beam. The laser irradiation unit 8 includes a laser oscillator (not depicted) of a YAG laser, a YVO₄ laser, a YLF laser, or the like and a laser processing head 10 disposed over the chuck table 4. An optical system that guides a laser beam 12 of pulse oscillation emitted from the laser oscillator to the object 11 is incorporated in the laser processing head 10. The optical system includes optical elements such as a collecting lens that focuses the laser beam 12. The laser beam 12 emitted from the laser oscillator is applied to the object 11 from the laser processing head 10 and is focused on a predetermined position. Then, predetermined laser processing is executed for the object 11 by the laser beam 12.

Moreover, the laser processing apparatus 2 includes a controller (control unit, control part, control apparatus) 14 that controls the laser processing apparatus 2. The controller 14 is connected to the respective constituent elements (chuck table 4, clamps 6, laser irradiation unit 8, and the like) configuring the laser processing apparatus 2, and outputs a control signal to the respective constituent elements. For example, the controller 14 is configured by a computer, and includes a processing section that executes processing of computation and the like required for operation of the laser processing apparatus 2 and a storage section that stores various kinds of information (data, program, and the like) used for the operation of the laser processing apparatus 2. The processing section includes a processor such as a central processing unit (CPU). The storage section includes a memory such as a read only memory (ROM) and a random access memory (RAM).

In processing the object 11 by the laser processing apparatus 2, first, the object 11 is held by the chuck table 4. For example, the object 11 is disposed on the chuck table 4 such that the side of the front surface 11a is oriented upward and the side of the back surface 11b (side of the sheet 21) faces the holding surface 4a. Further, the frame 19 is fixed by the plurality of clamps 6. When a suction force (negative pressure) of the suction source is made to act on the holding surface 4a in this state, the object 11 is sucked and held by the chuck table 4 with the interposition of the sheet 21.

Next, the chuck table 4 rotates, and the angle of the chuck table 4 is adjusted such that the length direction of the predetermined planned dividing line 13 (see FIG. 3) corresponds with the X-axis direction. Further, the position of the chuck table 4 in the Y-axis direction is adjusted such that a region to be irradiated with the laser beam 12 is positioned on an extended line of the predetermined planned dividing line 13. Moreover, the height position of the laser processing head 10 and the arrangement of the optical system are adjusted to position the focal point of the laser beam 12 at the same height position (position in the Z-axis direction) as the inside of the object 11 (between the front surface 11a and the back surface 11b).

Then, the chuck table 4 is moved along the X-axis direction while irradiation with the laser beam 12 from the laser processing head 10 is executed. Thereby, the chuck table 4 and the laser beam 12 relatively move along the processing feed direction at a predetermined processing feed rate. As a result, irradiation with the laser beam 12 is executed along the planned dividing line 13 from the side of the front surface 11a of the object 11.

Note that the laser processing apparatus 2 processes the object 11 under predetermined processing conditions registered in the controller 14 in advance. For example, irradiation configurations of the laser beam 12 are set to cause a region irradiated with the laser beam 12 in the object 11 to be modified and alter due to multi-photon absorption. Specifically, the wavelength of the laser beam 12 is set to cause at least part of the laser beam 12 to be transmitted through the object 11. That is, the laser beam 12 is a laser beam having transmissibility with respect to the object 11. Further, other irradiation conditions of the laser beam 12 are also set to cause the object 11 to be properly modified. For example, when the object 11 is a single-crystal silicon wafer, irradiation conditions of the laser beam 12 can be set as follows.
Wavelength: 1064 nm
Average output power: 1 W
Repetition frequency: 100 kHz
Processing feed rate: 800 mm/s

When the object 11 is processed under the above-described processing conditions, the inside of the object 11 is modified and alters due to multi-photon absorption, and a modified layer (altered layer) 11c is formed inside the object 11 along the planned dividing line 13. Thereafter, irradiation with the laser beam 12 is executed along the other planned dividing lines 13 by repeating a similar procedure. As a result, a plurality of modified layers 11c are formed inside the object 11 in a lattice manner along all planned dividing lines 13.

A region in which the modified layer 11c has been formed in the object 11 becomes more fragile than the other region in the object 11. Thus, when an external force is given to the object 11, the object 11 is divided along the planned dividing line 13, with the modified layer 11c being the origin. That is, the modified layer 11c functions as the origin of dividing (trigger for dividing).

Note that a plurality of modified layers 11c may be formed in the thickness direction of the object 11. For example, when the object 11 is a single-crystal silicon wafer or the like with a thickness of 200 μm or larger, proper dividing of the object 11 is facilitated by forming two or more modified layers 11c. In a case of forming the plurality of modified layers 11c, irradiation with the laser beam 12 is executed multiple times along each planned dividing line 13 while the height position of the focal point of the laser beam 12 is varied.

Next, by giving an external force to the object 11, the object 11 is divided along the planned dividing lines 13 with use of the modified layers 11c as the origin (external force giving step). For example, in the external force giving step, the external force is given to the object 11 by pulling and expanding the sheet 21 fixed to the object 11. Note that the expansion of the sheet 21 may be executed by using a dedicated expanding apparatus, or may be manually executed by a worker.

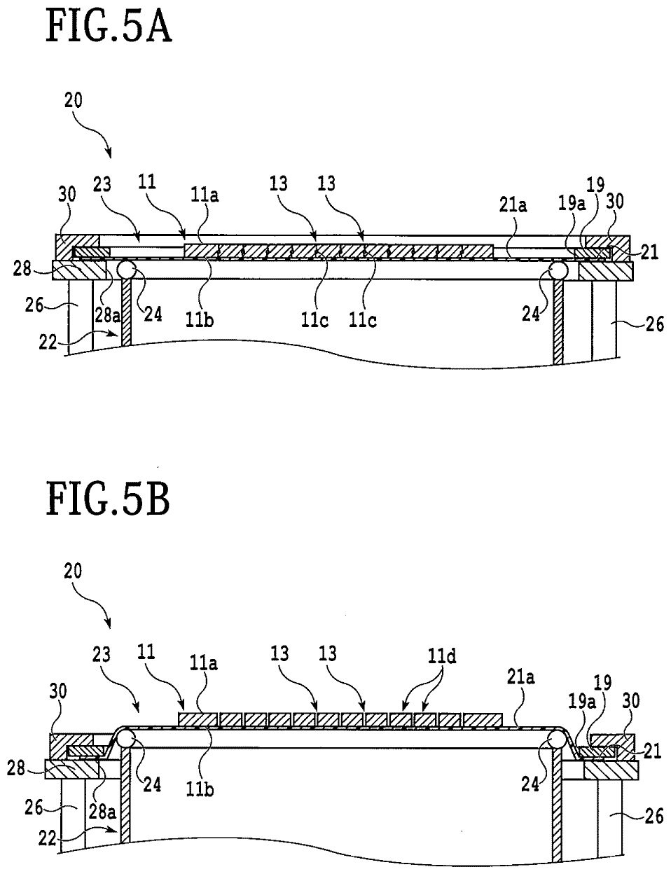

FIG. 5A is a partially sectional front view depicting an expanding apparatus 20. The expanding apparatus 20 includes a drum 22 formed into a hollow circular column shape. At an upper end portion of the drum 22, a plurality of rollers 24 are arranged at a substantially equal interval along the circumferential direction of the drum 22. Further, a plurality of columnar support members 26 are disposed outside the drum 22. A raising-lowering mechanism (not depicted) that raises and lowers the support member 26 along the vertical direction is coupled to each of lower end portions of the support members 26. For example, a linear actuator, an air cylinder, or the like is used as the raising-lowering mechanism.

An annular table 28 is fixed to upper end portions of the plurality of support members 26. A circular opening 28a that penetrates the table 28 in the thickness direction is made at a central portion of the table 28. The diameter of the opening 28a is larger than that of the drum 22, and the upper end portion of the drum 22 can be inserted into the opening 28a. Moreover, a plurality of clamps 30 that grasp and fix the frame 19 that supports the object 11 are disposed at an outer circumferential portion of the table 28. When the plurality of support members 26 are raised and lowered by the raising-lowering mechanisms (not depicted), the table 28 and the frame 19 rise and lower along the vertical direction.

In dividing the object 11, first, the support members 26 are raised and lowered by the raising-lowering mechanisms (not depicted), and the table 28 is disposed at an initial position. When the table 28 is disposed at the initial position, the upper surface of the table 28 and the upper ends of the rollers 24 are disposed at substantially the same height position. Then, the frame 19 is disposed on the table 28, and the frame 19 is fixed by the plurality of clamps 30. At this time, the object 11 is disposed to overlap with the inside of the drum 22, and the non-fixed region 21a of the sheet 21 is supported by the plurality of rollers 24. Thereafter, the support members 26 are lowered to lower the table 28 and the clamps 30. Thereby, the frame 19 is pressed down, and the sheet 21 is pulled in the state in which the non-fixed region 21a is supported by the plurality of rollers 24. As a result, the sheet 21 radially extends to be expanded.

FIG. 5B is a partially sectional front view depicting the expanding apparatus 20 that expands the sheet 21. When the sheet 21 is expanded, an external force toward the outside of the object 11 in the radial direction is given to the object 11 fixed to the sheet 21. As a result, the object 11 breaks along the planned dividing lines 13, with the modified layers 11c being the origin of dividing. Due to this, the object 11 is divided into a plurality of chips (device chips) 11d each including the device 15 (see FIG. 3). When the dividing of the object 11 has been completed, the support members 26 rise and the table 28 is disposed at the initial position again.

As described above, the plurality of chips 11d are manufactured when the object 11 is divided along the planned dividing lines 13 in the treatment step S2. That is, the treatment method for a sheet according to the present embodiment corresponds to a manufacturing method for a chip by which the object 11 is divided to manufacture the chips 11d.

Here, when the sheet 21 is expanded, a large stretch is caused in the non-fixed region 21a of the sheet 21, and loosening occurs in the non-fixed region 21a when the table 28 is returned to the initial position. Further, if the loosening occurs in the non-fixed region 21a of the sheet 21, inconvenience is caused in handling of the object 11. For example, if the object 11 is conveyed from the expanding apparatus 20 in a state in which loosening has occurred in the non-fixed region 21a, a state in which the object 11 droops from the frame 19 is made, and a swing is likely to occur in the object 11. Thus, there is a possibility that the chips 11d collide with each other and the chip 11d is damaged.

Thus, in the present embodiment, after the dividing of the object 11 is completed, the non-fixed region 21a of the sheet 21 is heated to be shrunk. Specifically, a light absorbing film is formed on the non-fixed region 21a of the sheet 21 (light absorbing film forming step S3). Thereafter, the non-fixed region 21a is heated to be shrunk by irradiating the light absorbing film with light and causing the light absorbing film to generate heat (shrinking step S4). This reduces or eliminates the loosening of the sheet 21, and it becomes possible to properly execute subsequent handling of the object 11.

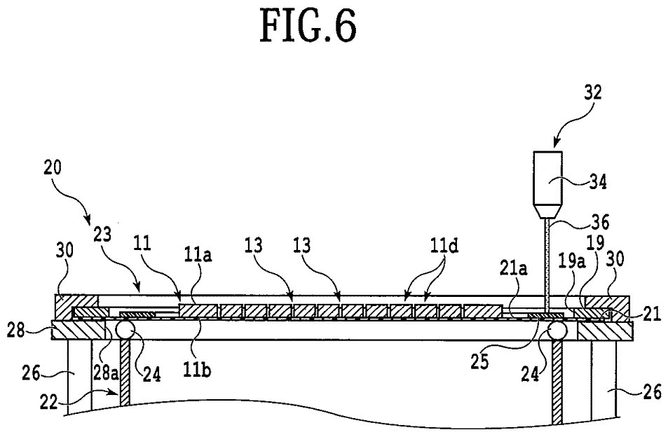

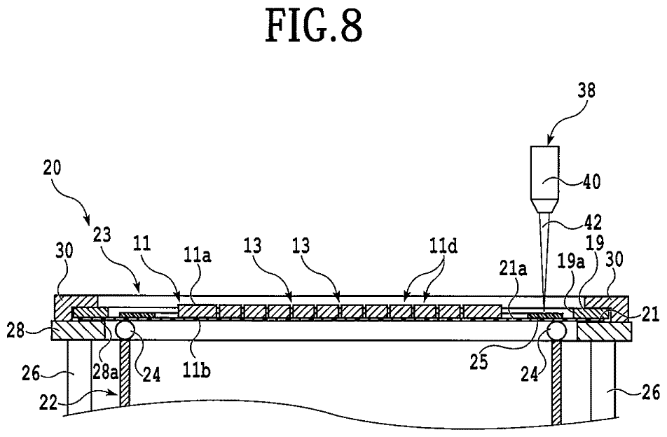

FIG. 6 is a partially sectional front view depicting the expanding apparatus 20 in the light absorbing film forming step S3. In the light absorbing film forming step S3, a light absorbing film 25 that absorbs light and generates heat is formed on the non-fixed region 21a of the sheet 21. The light absorbing film 25 is a film having a property of absorbing light 42 (see FIG. 8) with which the sheet 21 is irradiated and generating heat in the shrinking step S4 to be described later. In the present embodiment, a case of executing the light absorbing film forming step S3 by using the expanding apparatus 20 is described.

The expanding apparatus 20 includes a light absorbing film forming unit 32 that forms the light absorbing film 25 on the sheet 21. The light absorbing film forming unit 32 includes a nozzle 34 that supplies a film material 36 that is a raw material of the light absorbing film 25. The nozzle 34 is set over the plurality of rollers 24 and the table 28, and is disposed at a position overlapping with the non-fixed region 21a of the sheet 21 supported by the plurality of rollers 24 and the table 28. The film material 36 is supplied from the nozzle 34 to the non-fixed region 21a of the sheet 21, and thereby the light absorbing film 25 is formed on the non-fixed region 21a.

Further, constituent elements of the expanding apparatus 20 are installed on, for example, a rotating table (not depicted). The rotating table is configured to rotate around a rotation axis that is substantially parallel to the vertical direction and is set to pass through the center of the table 28. When the rotating table is actuated, the constituent elements of the expanding apparatus 20 (drum 22, rollers 24, support members 26, table 28, clamps 30, and the like) rotate around the rotation axis of the rotating table. Thus, the frame unit 23 held by the constituent elements of the expanding apparatus 20 also rotates.

In the light absorbing film forming step S3, the frame unit 23 is rotated while the film material 36 is supplied from the nozzle 34 toward the non-fixed region 21a of the sheet 21. Thereby, the film material 36 is annularly supplied along the circumferential direction of the non-fixed region 21a, and part or the whole of the non-fixed region 21a is covered by the film material 36. Thereafter, by drying the film material 36, the annular light absorbing film 25 in contact with part or the whole of the non-fixed region 21a is formed.

However, the nozzle 34 may be turned instead of rotating the frame unit 23. For example, a turning arm (not depicted) that turns the nozzle 34 along an annular path overlapping with the non-fixed region 21a of the sheet 21 is connected to the nozzle 34. In this case, the film material 36 can be annularly supplied along the circumferential direction of the non-fixed region 21a of the sheet 21 by actuating the turning arm to turn the nozzle 34 while supplying the film material 36 from the nozzle 34 to the non-fixed region 21a.

By supplying the film material 36 to the non-fixed region 21a of the sheet 21 in the above-described manner, the annular light absorbing film 25 is formed on the non-fixed region 21a. The light absorbing film 25 is formed between the object 11 and the frame 19 in such a manner as to be in contact with part or the whole of the non-fixed region 21a.

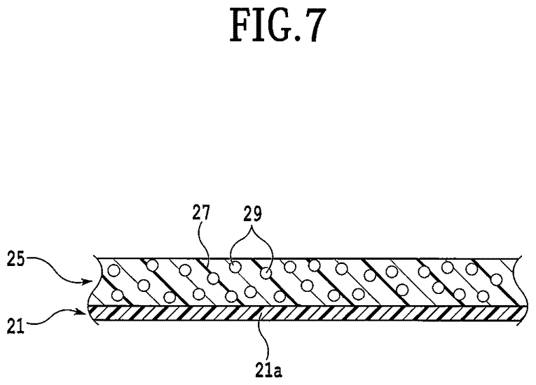

FIG. 7 is a sectional view depicting part of the sheet 21 and the light absorbing film 25. For example, the light absorbing film 25 is formed of a resin film 27 containing a light absorbing agent 29 that absorbs light and generates heat. The light absorbing agent 29 is a granular or powder-like substance that absorbs light in a predetermined wavelength band and generates heat, and is substantially evenly dispersed across the whole of the inside of the resin film 27.

The resin film 27 is formed by applying the film material 36 (see FIG. 6) containing the light absorbing agent 29 to the non-fixed region 21a of the sheet 21. For example, a liquid resin generated by dissolving a solute composed of a water-soluble resin in a solvent such as water is used as the film material 36. Specific examples of the water-soluble resin include polyvinyl alcohol (PVA), polyvinylpyrrolidone (PVP), hydroxypropyl cellulose, polyethylene glycol, polyethylene oxide, methylcellulose, ethylcellulose, polyacrylic acid, poly(N-vinylacetamide), polystyrene sulfonate, special nylon, phenol resin, methylol melamine resin, polyglycerin, and the like. Further, it is also possible to use a graft polymer of the above-described respective resins as the water-soluble resin.

In addition, the light absorbing agent 29 is added to the liquid resin. The light absorbing agent 29 is composed of a material that absorbs the light 42 (see FIG. 8) with which the sheet 21 is irradiated and generates heat in the shrinking step S4 to be described later. For example, when the sheet 21 is irradiated with infrared with a wavelength of at least 700 nm and at most 1300 nm in the shrinking step S4, it is possible to use, as the light absorbing agent 29, a cinnamic acid-based organic compound (ferulic acid or the like), a benzophenone-based organic compound, metal oxide (zinc oxide, titanium oxide, or the like) carbon, or the like that absorbs the infrared and generates heat.

By supplying the film material 36 generated in the above-described manner to the non-fixed region 21a of the sheet 21 and drying the film material 36, the resin film 27 containing the light absorbing agent 29 is formed on the non-fixed region 21a. Then, when the resin film 27 is irradiated with light, the light absorbing agent 29 contained in the resin film 27 absorbs the light and generates heat, and the resin film 27 is heated. Incidentally, when the resin film 27 is composed of the water-soluble resin, in removal of the resin film 27 in a later step, the resin film 27 can be removed by a simple process of supplying water to the resin film 27.

However, there is no limit on the material, configuration, shape, forming method, and the like of the light absorbing film 25 as long as the light absorbing film 25 has the property of absorbing light and generating heat. For example, the light absorbing film 25 may be a film composed of a material other than the resin (metal film or the like). Moreover, when a base material (matrix) of the light absorbing film 25 has a property of absorbing light and generating heat, the light absorbing agent 29 does not necessarily have to be contained in the light absorbing film 25.

Further, although the example in which the light absorbing film 25 is formed on the upper surface side of the sheet 21 is depicted in FIG. 6, the light absorbing film 25 may be formed on the lower surface side of the sheet 21. In this case, the light absorbing film 25 may be formed on only part of the sheet 21 (region overlapping with the non-fixed region 21a), or may be formed on the whole of the lower surface side of the sheet 21. Moreover, the light absorbing film 25 with a sheet shape may be applied to the non-fixed region 21a of the sheet 21 after being formed independently of the sheet 21.

FIG. 8 is a partially sectional front view depicting the expanding apparatus 20 in the shrinking step S4. In the shrinking step S4, the non-fixed region 21a of the sheet 21 is heated to be shrunk by irradiating the light absorbing film 25 with light and causing the light absorbing film 25 to generate heat. In the present embodiment, a case of executing the shrinking step S4 by using the expanding apparatus 20 is described.

The expanding apparatus 20 includes a light irradiation unit 38 that irradiates the light absorbing film 25 with light. For example, the light irradiation unit 38 includes a light irradiation head 40 that executes irradiation with the light 42. The light irradiation head 40 is set at a position overlapping with the light absorbing film 25 formed on the non-fixed region 21a of the sheet 21. When the light absorbing film 25 is irradiated with the light 42 from the light irradiation head 40, the light absorbing film 25 absorbs the light 42 and generates heat.

For example, the light irradiation unit 38 is a laser irradiation unit that executes irradiation with a laser beam as the light 42. In this case, the light irradiation unit 38 can be configured similarly to the laser irradiation unit 8 (see FIG. 4), and an optical system including optical elements such as a collecting lens is housed in the light irradiation head 40. Further, the wavelength of the light 42 is set to cause the light 42 to be absorbed by the light absorbing film 25. For example, the wavelength of the light 42 is set to at least 700 nm and at most 1300 nm (typically, 940 nm, 1064 nm, or the like).

In the shrinking step S4, the light irradiation unit 38 is actuated, and the light absorbing film 25 is irradiated with the light 42 from the light irradiation head 40. As a result, the light 42 is absorbed by the light absorbing film 25 and is converted to heat, and the light absorbing film 25 generates heat. In addition, when the light absorbing film 25 generates heat, the non-fixed region 21a of the sheet 21 in contact with the light absorbing film 25 is heated. This shrinks the non-fixed region 21a, and loosening that has occurred in the non-fixed region 21a is reduced or eliminated.

Moreover, the frame unit 23 is rotated while the light absorbing film 25 is irradiated with the light 42 from the light irradiation head 40. Thereby, scanning with the light 42 is annularly executed along the circumferential direction of the light absorbing film 25, and the whole of the light absorbing film 25 is irradiated with the light 42. As a result, the whole of the non-fixed region 21a in contact with the light absorbing film 25 is heated, and loosening of the sheet 21 is reduced or eliminated across the whole of the non-fixed region 21a.

The annular scanning with the light 42 may be executed by turning the light irradiation head 40 instead of rotating the frame unit 23 and the light absorbing film 25. For example, a turning arm (not depicted) that turns the light irradiation head 40 along an annular path overlapping with the light absorbing film 25 is connected to the light irradiation head 40. In this case, scanning with the light 42 can be annularly executed along the circumferential direction of the light absorbing film 25 by actuating the turning arm to turn the light irradiation head 40 while irradiating the light absorbing film 25 with the light 42 from the light irradiation head 40.

FIG. 8 depicts the example in which the light irradiation head 40 is disposed on the upper side of the sheet 21 and the light absorbing film 25. However, it is also possible to dispose the light irradiation head 40 on the lower side of the sheet 21 and the light absorbing film 25. In this case, the light 42 emitted from the light irradiation head 40 is transmitted through the sheet 21 and is absorbed by the light absorbing film 25, and the light absorbing film 25 generates heat.

As described above, by irradiating the light absorbing film 25 formed on the non-fixed region 21a of the sheet 21 with the light 42, the non-fixed region 21a can be heated to be shrunk even when the sheet 21 does not have absorbability with respect to the light 42. This makes it possible to suppress loosening of the sheet 21 irrespective of the material of the sheet 21.

Note that, in the above description, the example in which the whole of the non-fixed region 21a of the sheet 21 is heated by the light absorbing film 25 has been described. However, in the shrinking step S4, only part of the non-fixed region 21a may be heated depending on characteristics of the sheet 21. For example, in a case in which loosening is particularly likely to occur in a predetermined region in the non-fixed region 21a of the sheet 21, only the region may be heated to be shrunk. Specifically, in the shrinking step S4, switching between irradiation and non-irradiation with the light 42 is executed at a predetermined timing while scanning with the light 42 is annularly executed along the light absorbing film 25. As a result, irradiation with the light 42 is intermittently executed along the light absorbing film 25, and the light absorbing film 25 is partly heated. This can heat only a desired region in the non-fixed region 21a.

Further, in a case of heating only part of the non-fixed region 21a, the light absorbing film 25 may be disposed in contact with only part of the non-fixed region 21a. In this case, the shape of the light absorbing film 25 does not necessarily have to be a circular annular shape corresponding to the shape of the non-fixed region 21a. For example, in the light absorbing film forming step S3, a plurality of light absorbing films 25 are formed at predetermined intervals along the circumferential direction of the non-fixed region 21a. Then, in the shrinking step S4, the plurality of light absorbing films 25 are sequentially irradiated with the light 42, and the non-fixed region 21a is partly heated.

Moreover, in the above description, the description has been given of the case in which the light absorbing film forming step S3 and the shrinking step S4 are executed to reduce or eliminate loosening of the sheet 21 after the loosening has occurred in the sheet 21 in the treatment step S2. However, it is also possible to suppress the loosening of the sheet 21 in the treatment step S2 in advance by preliminarily executing the light absorbing film forming step S3 and the shrinking step S4 before execution of the treatment step S2. Specifically, before execution of the treatment step S2, the non-fixed region 21a of the sheet 21 is heated by the above-described procedure to be shrunk (light absorbing film forming step S3 and shrinking step S4). This makes a state in which the non-fixed region 21a of the sheet 21 is strained more strongly than the other region, and the tension of the non-fixed region 21a becomes higher than that of the other region. Thus, even when subsequently the sheet 21 is expanded in the treatment step S2, the non-fixed region 21a of the sheet 21 stretches less readily, and the possibility of occurrence of loosening in the non-fixed region 21a decreases. Due to this, the loosening of the sheet 21 is suppressed in advance.

As described above, in the treatment method for a sheet (manufacturing method for a chip) according to the present embodiment, the non-fixed region 21a of the sheet 21 is heated to be shrunk by irradiating the light absorbing film 25 formed on the non-fixed region 21a with the light 42 and causing the light absorbing film 25 to generate heat. Due to this, work of setting irradiation conditions of the light 42 in detail depending on the material of the sheet 21 becomes unnecessary, and treatment of suppressing loosening of the sheet 21 is simplified.

Note that, in the above-described embodiment, the description has been given of the case in which the light absorbing film forming step S3 (see FIG. 6) is executed to form the light absorbing film 25 after the treatment step S2 (see FIGS. 4 to 5B). However, the timing of the formation of the light absorbing film 25 can be changed as appropriate as long as the timing is before the shrinking step S4 (see FIG. 8). For example, the light absorbing film forming step S3 may be executed after the preparation step S1 and before the treatment step S2.

Further, in the above-described embodiment, the description has been given of the case in which, in the treatment step S2, treatment of giving an external force to the object 11 by expanding the sheet 21 is executed. However, there is no limit on the treatment executed for the object 11 in the treatment step S2. Other examples of the treatment step S2 are described in a second embodiment and a third embodiment to be described later.

Moreover, in the above-described embodiment, the description has been given of the case in which the light absorbing film forming step S3 (see FIG. 6) and the shrinking step S4 (see FIG. 8) are executed by using the expanding apparatus 20. However, the light absorbing film forming step S3 and the shrinking step S4 may be executed by a sheet treatment apparatus prepared separately from the expanding apparatus 20. In this case, the sheet treatment apparatus includes the above-described light absorbing film forming unit 32 and light irradiation unit 38. Further, after expansion of the sheet 21 by the expanding apparatus 20 is executed, formation of the light absorbing film 25 and heating of the non-fixed region 21a of the sheet 21 are executed by the sheet treatment apparatus, and loosening of the sheet 21 is suppressed.

Besides, structures, methods, and the like according to the present embodiment can be carried out with appropriate changes without departing from the scope of the object of the present invention.

### Second Embodiment

In the above-described first embodiment, the description has been given of the case in which loosening occurs in the sheet 21 when an external force is given to the object 11 by expansion of the sheet 21. In the present embodiment, as another example of the treatment executed for the object, processing of separating an annular reinforcing portion from the object for which the TAIKO grinding has been executed is described.

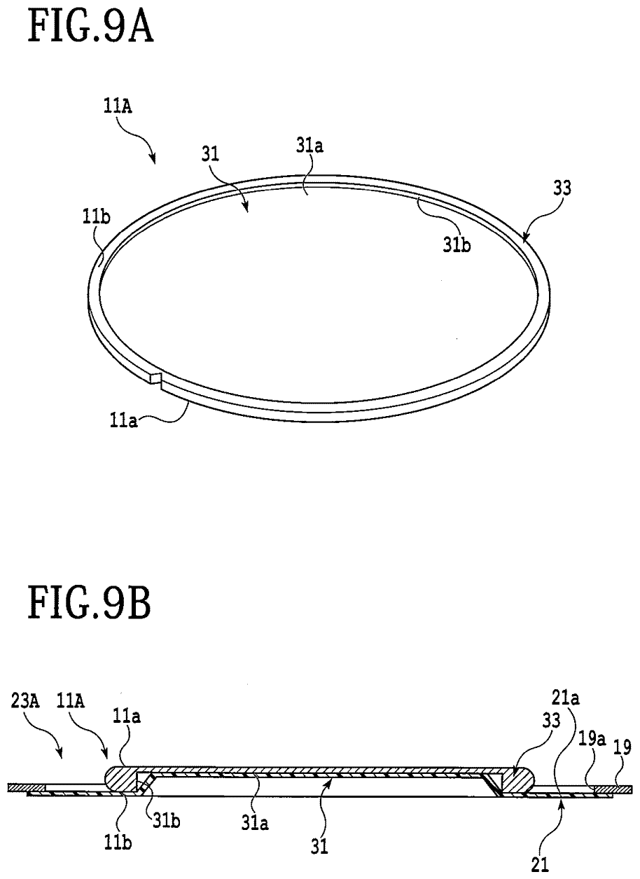

FIG. 9A is a perspective view depicting an object 11A that is a modification of the object 11. The configuration, material, and the like of the object 11A are similar to those of the object 11 (see FIG. 2) except for matters to be described below. For example, the object 11A is a circular disc-shaped wafer composed of a semiconductor material such as single-crystal silicon, and includes the front surface 11a and the back surface 11b substantially parallel to each other. Further, the plurality of devices 15 (see FIG. 2) are formed on the side of the front surface 11a of the object 11A, and the object 11A has the device region 17A and the outer circumferential surplus region 17B (see FIG. 2). By dividing the object 11A along the planned dividing lines 13 (see FIG. 2), the plurality of chips 11d (see FIG. 5B) each including the device 15 are manufactured. Moreover, the thinned chips 11d are obtained by grinding and thinning the object 11A before the dividing.

For example, a grinding apparatus is used for the thinning of the object 11A. The grinding apparatus includes a chuck table (holding table) that holds the object 11A and a grinding unit that executes grinding processing for the object 11A. An annular grinding wheel including a plurality of grinding abrasive stones is mounted on the grinding unit. The object 11A is held by the chuck table, and the grinding abrasive stones are brought into contact with the side of the back surface 11b of the object 11A while the chuck table and the grinding wheel are rotated. Thereby, the side of the back surface 11b of the object 11A is ground, and the object 11A is thinned.

However, when the whole of the side of the back surface 11b of the object 11A is ground, the whole of the object 11A is thinned and the rigidity of the object 11A lowers. Due to this, the possibility of occurrence of deformation or breakage of the object 11A increases, and handling of the object 11A after the thinning is difficult. Thus, thinning treatment is sometimes executed for only a partial region on the side of the back surface 11b of the object 11A. Specifically, the TAIKO grinding to grind only a central portion of the object 11A is executed for the object 11A. In this case, a circular recess portion (groove) 31 is formed in the back surface 11b of the object 11A. The recess portion 31 is made at a position corresponding to the device region 17A (see FIG. 2). For example, the diameter of the recess portion 31 is substantially the same as that of the device region 17A, and the recess portion 31 is formed at a position overlapping with the device region 17A.

The recess portion 31 includes a circular bottom surface 31a substantially parallel to the front surface 11a and the back surface 11b of the object 11A, and an annular side surface (inner wall) 31b that is substantially parallel to the thickness direction of the object 11A and is connected to the back surface 11b and the bottom surface 31a. Further, an annular reinforcing portion (projection portion) 33 corresponding to a region for which the thinning treatment (grinding processing) is not executed remains at an outer circumferential portion of the object 11A. The reinforcing portion 33 includes the outer circumferential surplus region 17B (see FIG. 2), and surrounds the device region 17A (see FIG. 2) and the recess portion 31.

When only the central portion of the object 11A is thinned, the outer circumferential portion (reinforcing portion 33) of the object 11A is kept in a thick state. Due to this, the lowering of the rigidity of the object 11A is suppressed, and the possibility of occurrence of deformation, breakage, or the like of the object 11A decreases. That is, the reinforcing portion 33 functions as an annular reinforcing member that reinforces the object 11A.

FIG. 9B is a sectional view depicting a frame unit 23A that is a modification of the frame unit 23. In executing predetermined treatment for the object 11A, the object 11A is supported by the frame 19 through the sheet 21. This forms the frame unit 23A including the object 11A, the frame 19, and the sheet 21.

In forming the frame unit 23A, the sheet 21 is fixed to the side of the back surface 11b of the object 11A and the frame 19. At this time, the sheet 21 is fixed along contours on the side of the back surface 11b of the object 11A while being pressed against the bottom surface 31a of the recess portion 31 and being stretched. Thereby, the sheet 21 is applied along the recess portion 31 and the back surface (lower surface) of the reinforcing portion 33. In addition, when the sheet 21 is fixed to the object 11A and the frame 19, the non-fixed region 21a that is fixed to neither the object 11A nor the frame 19 in the sheet 21 is formed. Details of the non-fixed region 21a of the sheet 21 are as described in the first embodiment (see FIG. 3 and the like).

In the preparation step S1, as described above, the object 11A in which the recess portion 31 is made at the central portion and the reinforcing portion 33 is made at the outer circumferential portion and for which the sheet 21 is fixed to the recess portion 31 and the reinforcing portion 33 is prepared. Although FIG. 9B depicts a case in which a slight gap (space) exists between the sheet 21 and the bottom surface 31a and the side surface 31b at an outer circumferential portion of the recess portion 31, the sheet 21 may be fixed in tight contact with the bottom surface 31a and the side surface 31b.

The object 11A for which the TAIKO grinding has been executed is subjected to treatment in such a state as to be supported by the frame 19 as described above. Then, after various kinds of treatment are executed for the object 11A, finally the reinforcing portion 33 is separated and removed from the object 11A. In the present embodiment, a description is given of a case in which the reinforcing portion 33 is separated from the object 11A in the treatment step S2. For example, the treatment step S2 includes a step of forming the origin of separation in the object 11A (origin-of-separation forming step) and a step of giving an external force to the object 11A (external force giving step).

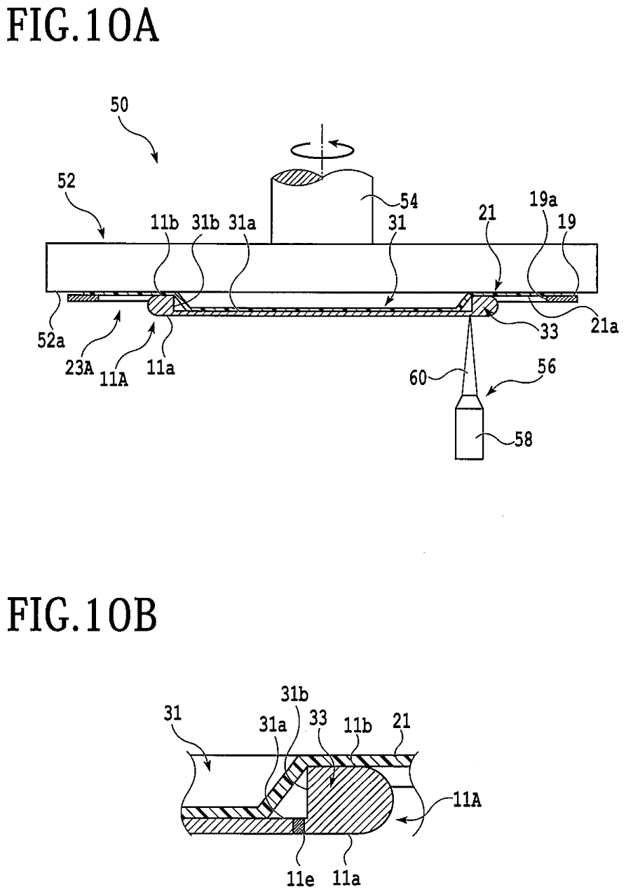

FIG. 10A is a partially sectional front view depicting a laser processing apparatus 50. For example, in the origin-of-separation forming step, a modified region that functions as the origin of separation is formed in the object 11A by executing laser processing for the object 11A by the laser processing apparatus 50.

The laser processing apparatus 50 includes a chuck table (holding table) 52 that holds the frame unit 23A. The lower surface of the chuck table 52 is a circular flat surface substantially parallel to a horizontal plane, and forms a holding surface 52a that holds the frame unit 23A. The holding surface 52a is connected to a suction source (not depicted) such as an ejector through a flow path (not depicted) formed inside the chuck table 52, a valve (not depicted), and the like.

A circular columnar support shaft 54 that supports the chuck table 52 is connected to the upper surface side of the chuck table 52. A tip portion (lower end portion) of the support shaft 54 is fixed to a central portion of the upper surface side of the chuck table 52. A rotational drive source (not depicted) such as a motor that rotates the support shaft 54 is coupled to a base end portion (upper end portion) of the support shaft 54. When the rotational drive source is actuated, the chuck table 52 and the support shaft 54 rotate around a rotation axis substantially parallel to the vertical direction. Moreover, a movement mechanism (not depicted) that moves the chuck table 52 and the support shaft 54 along the horizontal direction and the vertical direction is coupled to the support shaft 54.

Further, the laser processing apparatus 50 includes a laser irradiation unit 56 that executes irradiation with a laser beam. The configuration and functions of the laser irradiation unit 56 are similar to those of the laser irradiation unit 8 (see FIG. 4) of the laser processing apparatus 2. Specifically, the laser irradiation unit 56 includes a laser oscillator (not depicted) and a laser processing head 58 disposed under the chuck table 52. An optical system that guides a laser beam 60 of pulse oscillation emitted from the laser oscillator to the object 11A is incorporated in the laser processing head 58. The optical system includes optical elements such as a collecting lens that focuses the laser beam 60. The laser beam 60 emitted from the laser oscillator is applied to the object 11A from the laser processing head 58 and is focused on a predetermined position. Then, predetermined laser processing is executed for the object 11A by the laser beam 60.

Moreover, the laser processing apparatus 50 includes a controller (not depicted) that controls the laser processing apparatus 50. The configuration and functions of the controller are similar to those of the controller 14 (see FIG. 4) of the laser processing apparatus 2.

In the origin-of-separation forming step, the origin of separation in separating the reinforcing portion 33 from the object 11A is formed. Specifically, first, the frame unit 23A is held by the chuck table 52. For example, the frame unit 23A gets contact with the holding surface 52a such that the side of the front surface 11a of the object 11A is oriented downward and the side of the back surface 11b of the object 11A (side of the sheet 21) faces the holding surface 52a. When a suction force (negative pressure) of the suction source is made to act on the holding surface 52a in this state, the object 11A and the frame 19 are sucked and held by the chuck table 52 with the interposition of the sheet 21. Note that the chuck table 52 may have a plurality of clamps (not depicted) that grasp the frame 19.

Next, a positional relation between the chuck table 52 and the laser processing head 58 in the horizontal direction is adjusted such that a region (processing-target region) in which the origin of separation of the object 11A is to be formed overlaps with the laser processing head 58 in the vertical direction. Further, the focusing position of the laser beam 60 is adjusted to focus the laser beam 60 on the processing-target region of the object 11A. In the present embodiment, the outer circumferential portion of the recess portion 31 (near the boundary between the recess portion 31 and the reinforcing portion 33) formed in the object 11A is set as the processing-target region. Then, the chuck table 52 is rotated while irradiation with the laser beam 60 from the laser processing head 58 is executed. Thereby, scanning with the laser beam 60 is annularly executed along the processing-target region (outer circumferential portion of the recess portion 31) of the object 11A. Irradiation conditions of the laser beam 60 can be set similarly to those in forming the modified layer 11c in the object 11 (see FIG. 4).

FIG. 10B is a sectional view depicting part of the object 11A in which a modified region (altered region) 11e has been formed. When the object 11A is irradiated with the laser beam 60 in the above-described manner, the inside of the object 11A is modified and alters due to multi-photon absorption, and the annular modified region 11e is formed in the outer circumferential portion of the recess portion 31 of the object 11A. Note that the modified region 11e may be formed to reach the bottom surface 31a of the recess portion 31 from the front surface 11a of the object 11A, or may be formed in a partial region between the front surface 11a of the object 11A and the bottom surface 31a of the recess portion 31.

A region in which the modified region 11e has been formed in the object 11A becomes more fragile than the other region in the object 11A. Thus, when an external force is given to the object 11A, the object 11A breaks, with the modified region 11e being the origin, and the reinforcing portion 33 is separated from the object 11A. That is, the modified region 11e functions as the origin of separation (trigger for separation).

Although the case in which the modified region 11e is formed in the object 11A has been described in the above description, the origin of separation is not limited to the modified region 11e. For example, a groove (laser-processed groove) that functions as the origin of separation may be formed at the outer circumferential portion of the recess portion 31 by executing ablation processing for the object 11A. In this case, the wavelength of the laser beam 60 is set to cause at least part of the laser beam 60 to be absorbed by the object 11A. That is, the laser beam 60 having absorbability with respect to the object 11A is used.

Next, by giving an external force to the object 11A, the reinforcing portion 33 is separated from the object 11A with use of the modified region 11e as the origin (external force giving step). For example, in the external force giving step, the external force is given by pressing a predetermined component (tool) against the reinforcing portion 33. Note that the separation of the reinforcing portion 33 from the object 11A may be executed by using a dedicated separating apparatus, or may be manually executed by a worker.

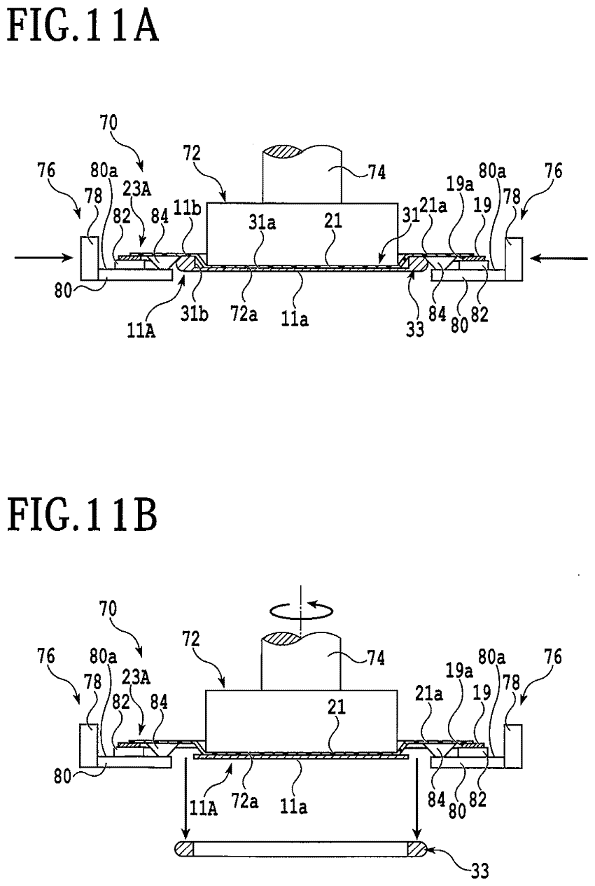

FIG. 11A is a partially sectional front view depicting a separating apparatus 70 when an external force is given to the object 11A. The separating apparatus 70 includes a chuck table (holding table) 72 that holds the object 11A. The lower surface of the chuck table 72 is a circular flat surface substantially parallel to a horizontal plane, and forms a holding surface 72a that holds the object 11A. The holding surface 72a is connected to a suction source (not depicted) such as an ejector through a flow path (not depicted) formed inside the chuck table 72, a valve (not depicted), and the like. Note that the diameter of the side of the holding surface 72a of the chuck table 72 is set smaller than that of the recess portion 31 formed in the object 11A. Thus, the side of the holding surface 72a of the chuck table 72 can be inserted into the recess portion 31 of the object 11A.

A circular columnar support shaft 74 that supports the chuck table 72 is connected to the upper surface side of the chuck table 72. A tip portion (lower end portion) of the support shaft 74 is fixed to a central portion of the upper surface side of the chuck table 72. A rotational drive source (not depicted) such as a motor that rotates the support shaft 74 is coupled to a base end portion (upper end portion) of the support shaft 74. When the rotational drive source is actuated, the chuck table 72 and the support shaft 74 rotate around a rotation axis substantially parallel to the vertical direction. Moreover, a movement mechanism (not depicted) that moves the chuck table 72 and the support shaft 74 along the horizontal direction and the vertical direction is coupled to the support shaft 74.

A pair of external force giving units 76 that give an external force to the object 11A are disposed on both lateral sides (right side and left right in FIG. 11A) of the chuck table 72. The pair of external force giving units 76 each include a columnar movable member 78 and a flat plate-shaped support member 80 that protrudes in the horizontal direction from a lower end portion of the movable member 78.

A movement mechanism (not depicted) that moves the movable member 78 along the horizontal direction and the vertical direction is coupled to the movable member 78. For example, the movement mechanism includes a linear actuator that moves the movable member 78 along the horizontal direction, and an air cylinder that moves (raises and lowers) the movable member 78 along the vertical direction. However, there is no limit on the kind, configuration, functions, and the like of the movement mechanism as long as the movement mechanism can move the movable member 78.

The support member 80 is fixed to the lower end portion of the movable member 78, and protrudes from the movable member 78 toward the chuck table 72. Further, the upper surface of the support member 80 is a flat surface substantially parallel to a horizontal plane, and forms a support surface 80a that supports constituent elements of the external force giving unit 76.

A frame support base 82 that supports the frame 19 is disposed on the support surface 80a of the support member 80. For example, the frame support base 82 is a circular disc-shaped member composed of a metal, resin, or the like, and supports the frame 19 from the lower side.

Moreover, a tool (pressing member) 84 that gives an external force to the reinforcing portion 33 of the object 11A is disposed on the support surface 80a of the support member 80. For example, the tool 84 is composed of a metal, resin, or the like, and is formed into an inverted truncated cone shape in which the diameter increases from the lower surface side toward the upper surface side. Thus, the angle formed by the upper surface and the side surface of the tool 84 is an acute angle, and a sharp corner portion is formed at an edge portion of the upper end side of the tool 84. However, the shape of the tool 84 is not limited to the inverted truncated cone shape, and may be, for example, an inverted truncated polygonal pyramid shape.

The tool 84 is disposed at a position closer to the chuck table 72 than the frame support base 82. That is, the tool 84 is disposed between the chuck table 72 and the frame support base 82 in plan view. Although FIG. 11A depicts one frame support base 82 and one tool 84 disposed on the support surface 80a of the support member 80, two or more frame support bases 82 and two or more tools 84 may be disposed on the support surface 80a of the support member 80.

In the external force giving step, first, the object 11A is held by the chuck table 72. Specifically, the object 11A is disposed on the lower side of the chuck table 72 such that the side of the front surface 11a is oriented downward and the side of the back surface 11b (side of the sheet 21) faces the holding surface 72a. At this time, the object 11A is positioned such that the side of the holding surface 72a of the chuck table 72 is inserted into the recess portion 31. When a suction force (negative pressure) of the suction source is made to act on the holding surface 72a in this state, the bottom surface 31a of the recess portion 31 of the object 11A is sucked and held by the chuck table 72 with the interposition of the sheet 21. Further, the pair of external force giving units 76 are positioned to cause the frame 19 to be supported by the frame support bases 82.

Next, the pair of external force giving units 76 come closer to each other to interpose the frame unit 23A therebetween. Thereby, the object 11A is interposed between the pair of tools 84. At this time, the side surfaces of the tools 84 get contact with the reinforcing portion 33 of the object 11A, and the upper end portions (corner portions) of the tools 84 enter a gap between the sheet 21 and the reinforcing portion 33. This gives obliquely downward external forces to the reinforcing portion 33. Moreover, the reinforcing portion 33 is partly peeled from the sheet 21, and a trigger for peeling-off of the reinforcing portion 33 from the sheet 21 is given.

Then, the chuck table 72 rotates in the state in which the tools 84 are in contact with the reinforcing portion 33. Thereby, the whole of the annular reinforcing portion 33 gets contact with the tools 84, and the external forces are given to the whole of the reinforcing portion 33. In addition, the trigger for peeling-off is formed for the whole of the annular contact region in which the sheet 21 is in contact with the reinforcing portion 33.

FIG. 11B is a partially sectional front view depicting the separating apparatus 70 when the reinforcing portion 33 is separated from the object 11A. When the external forces are given to the reinforcing portion 33 in the above-described manner, the object 11A breaks, with the annular modified region 11e (see FIG. 10B) being the origin. This separates the reinforcing portion 33 from the object 11A. Further, the reinforcing portion 33 is peeled off from the sheet 21 and drops. In this manner, the reinforcing portion 33 is removed from the object 11A.

In the case in which the tool 84 is formed into the inverted truncated cone shape, the tool 84 may be configured to be rotatable around its center axis as the rotation axis. In this case, when the chuck table 72 is rotated, the tool 84 rotates in association with rotation of the object 11A. This reduces friction that acts between the reinforcing portion 33 and the tool 84, and it becomes possible to smoothly rotate the object 11A.

As described above, when the reinforcing portion 33 has been separated from the object 11A in the treatment step S2, the part other than the reinforcing portion 33 in the object 11A remains as a plate-shaped substrate. That is, the treatment method for a sheet according to the present embodiment corresponds to a manufacturing method for a substrate by which the object 11A is processed to manufacture the substrate.

Here, as described above, in the case in which the recess portion 31 is made in the object 11A, the sheet 21 is fixed in such a state as to be pressed against the bottom surface 31a of the recess portion 31 and is stretched (see FIG. 9B). Then, when the reinforcing portion 33 has been separated from the object 11A in the treatment step S2, tension of the sheet 21 fixed to the recess portion 31 of the object 11A is released, and loosening occurs in the non-fixed region 21a of the sheet 21.

Thus, in the present embodiment, after the reinforcing portion 33 is separated from the object 11A, the light absorbing film forming step S3 and the shrinking step S4 are executed, and thereby the non-fixed region 21a of the sheet 21 is heated to be shrunk and the loosening of the sheet 21 is reduced or eliminated. The contents of the light absorbing film forming step S3 and the shrinking step S4 is similar to that in the first embodiment except for matters to be described below (see FIGS. 6 and 8).

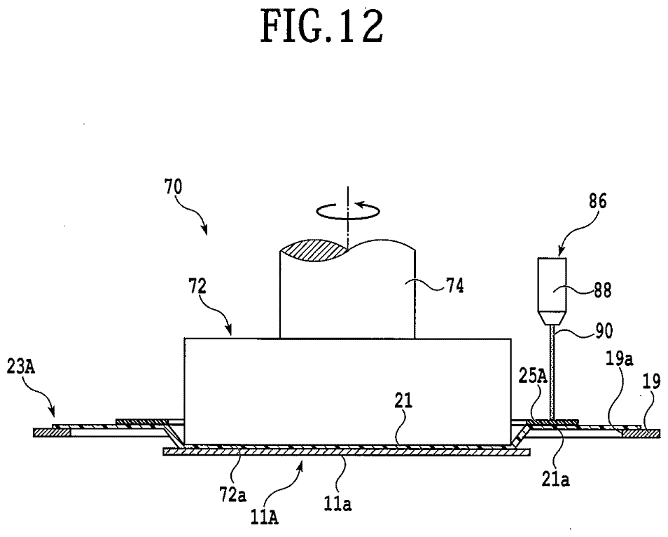

FIG. 12 is a partially sectional front view depicting the separating apparatus 70 in the light absorbing film forming step S3. In the present embodiment, a case of executing the light absorbing film forming step S3 by using the separating apparatus 70 is described.

The separating apparatus 70 includes a light absorbing film forming unit 86 that forms a light absorbing film 25A on the sheet 21. The light absorbing film forming unit 86 is configured similarly to the light absorbing film forming unit 32 (see FIG. 6) of the expanding apparatus 20.

For example, the light absorbing film forming unit 86 includes a nozzle 88 that supplies a film material 90 that is a raw material of the light absorbing film 25A. The nozzle 88 is disposed at a position overlapping with the non-fixed region 21a of the sheet 21 included in the frame unit 23A held by the chuck table 72. By supplying the film material 90 from the nozzle 88 to the non-fixed region 21a of the sheet 21, the light absorbing film 25A that absorbs light and generates heat is formed on the non-fixed region 21a. Note that specific examples of the film material 90 are similar to those of the film material 36 (see FIG. 6) supplied from the light absorbing film forming unit 32 in the first embodiment.

In the light absorbing film forming step S3, the chuck table 72 is rotated together with the frame unit 23A while the film material 90 is supplied from the nozzle 88 toward the non-fixed region 21a of the sheet 21. Thereby, the film material 90 is annularly supplied along the circumferential direction of the non-fixed region 21a, and part or the whole of the non-fixed region 21a is covered by the film material 90. Thereafter, by drying the film material 90, the light absorbing film 25A in contact with part or the whole of the non-fixed region 21a is formed. For example, the light absorbing film 25A is formed of the resin film 27 (see FIG. 7) containing the light absorbing agent 29.

The nozzle 88 may be turned instead of rotating the frame unit 23A. For example, a turning arm (not depicted) that turns the nozzle 88 along an annular path overlapping with the non-fixed region 21a of the sheet 21 is connected to the nozzle 88. In this case, the film material 90 can be annularly supplied along the circumferential direction of the non-fixed region 21a of the sheet 21 by actuating the turning arm to turn the nozzle 88 while supplying the film material 90 from the nozzle 88 to the non-fixed region 21a.

By supplying the film material 90 to the non-fixed region 21a of the sheet 21 in the above-described manner, the annular light absorbing film 25A is formed on the non-fixed region 21a. The light absorbing film 25A is formed between the object 11A and the frame 19 in such a manner as to be in contact with part or the whole of the non-fixed region 21a. Although the example in which the light absorbing film 25A is formed on the upper surface side of the non-fixed region 21a of the sheet 21 is depicted in FIG. 12, the light absorbing film 25A may be formed on the lower surface side of the non-fixed region 21a of the sheet 21.

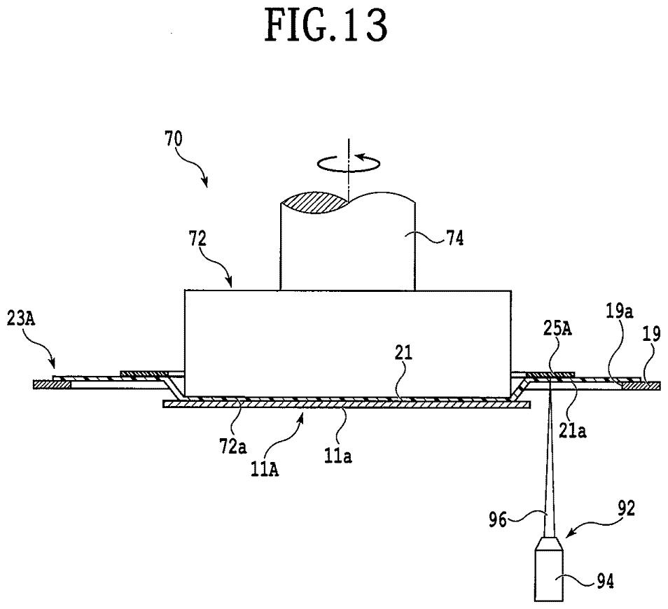

FIG. 13 is a partially sectional front view depicting the separating apparatus 70 in the shrinking step S4. In the present embodiment, a case of executing the shrinking step S4 by using the separating apparatus 70 is described.

The separating apparatus 70 includes a light irradiation unit 92 that irradiates the light absorbing film 25A with light. For example, the light irradiation unit 92 includes a light irradiation head 94 that executes irradiation with light 96. The light irradiation head 94 is set at a position overlapping with the light absorbing film 25A formed on the non-fixed region 21a of the sheet 21. Through irradiation of the light absorbing film 25A with the light 96 from the light irradiation head 94, the light absorbing film 25A absorbs the light 96 and generates heat.

The light irradiation unit 92 is configured similarly to the light irradiation unit 38 (see FIG. 8) of the expanding apparatus 20. For example, the light irradiation unit 92 is a laser irradiation unit that executes irradiation with a laser beam as the light 96. The wavelength of the light 96 is set as appropriate to cause the light 96 to be absorbed by the light absorbing film 25A.

In the shrinking step S4, the light irradiation unit 92 is actuated, and the light 96 is emitted from the light irradiation head 94 toward the light absorbing film 25A. Then, the light 96 is transmitted through the sheet 21 and reaches the light absorbing film 25A, and is absorbed to be converted to heat by the light absorbing film 25A. Due to this, the light absorbing film 25A generates heat, and the non-fixed region 21a of the sheet 21 in contact with the light absorbing film 25A is heated. As a result, the non-fixed region 21a shrinks, and loosening that has occurred in the non-fixed region 21a is reduced or eliminated.

Moreover, the chuck table 72 is rotated while the light absorbing film 25A is irradiated with the light 96 from the light irradiation head 94. Due to this, the light absorbing film 25A rotates together with the frame unit 23A, and scanning with the light 96 is annularly executed along the circumferential direction of the light absorbing film 25A. Then, irradiation with the light 96 is executed across the whole of the light absorbing film 25A, and the whole of the non-fixed region 21a in contact with the light absorbing film 25A is heated. As a result, loosening of the sheet 21 is reduced or eliminated across the whole of the non-fixed region 21a.

The annular scanning with the light 96 may be executed by turning the light irradiation head 94 instead of rotating the frame unit 23A and the light absorbing film 25A. For example, a turning arm (not depicted) that turns the light irradiation head 94 along an annular path overlapping with the light absorbing film 25A is connected to the light irradiation head 94. In this case, scanning with the light 96 can be annularly executed along the circumferential direction of the light absorbing film 25A by actuating the turning arm to turn the light irradiation head 94 while irradiating the light absorbing film 25A with the light 96 from the light irradiation head 94.

Note that FIG. 13 depicts the example in which the light irradiation head 94 is disposed on the lower side of the sheet 21 and the light absorbing film 25A. However, it is also possible to dispose the light irradiation head 94 on the upper side of the sheet 21 and the light absorbing film 25A. In this case, the light absorbing film 25A is directly irradiated with the light 96 emitted from the light irradiation head 94, and the light 96 is absorbed by the light absorbing film 25A.

As described above, by irradiating the light absorbing film 25A in contact with the non-fixed region 21a of the sheet 21 with the light 96, the non-fixed region 21a can be heated to be shrunk even when the sheet 21 does not have absorbability with respect to the light 96. This makes it possible to suppress loosening of the sheet 21 irrespective of the material of the sheet 21.

Incidentally, in the above description, the example in which the whole of the non-fixed region 21a of the sheet 21 is heated by the light absorbing film 25A has been described. However, in the shrinking step S4, only part of the non-fixed region 21a may be heated depending on characteristics of the sheet 21. For example, in a case in which loosening is particularly likely to occur in a predetermined region in the non-fixed region 21a of the sheet 21, only the region may be heated to be shrunk. A specific example of the method for heating only part of the non-fixed region 21a is similar to that in the first embodiment.

Incidentally, in the above description, the description has been given of the case in which the light absorbing film forming step S3 and the shrinking step S4 are executed to reduce or eliminate loosening of the sheet 21 after the loosening has occurred in the sheet 21 in the treatment step S2. However, it is also possible to suppress the loosening of the sheet 21 in the treatment step S2 in advance by preliminarily executing the light absorbing film forming step S3 and the shrinking step S4 before execution of the treatment step S2. Specifically, before execution of the treatment step S2, the non-fixed region 21a of the sheet 21 is heated by the above-described procedure to be shrunk (light absorbing film forming step S3 and shrinking step S4). This makes a state in which the non-fixed region 21a of the sheet 21 is strained more strongly than the other region, and the tension of the non-fixed region 21a becomes higher than that of the other region. Thus, even when subsequently the reinforcing portion 33 is separated from the object 11A in the treatment step S2, loosening is less likely to occur in the non-fixed region 21a. Due to this, the loosening of the sheet 21 is suppressed in advance.

As described above, in the treatment method for a sheet (manufacturing method for a substrate) according to the present embodiment, the non-fixed region 21a of the sheet 21 is heated to be shrunk by irradiating the light absorbing film 25A formed on the non-fixed region 21a with the light 96 and causing the light absorbing film 25A to generate heat. Due to this, work of setting irradiation conditions of the light 96 in detail depending on the material of the sheet 21 becomes unnecessary, and treatment of suppressing loosening of the sheet 21 is simplified.

In the above-described embodiment, the description has been given of the case in which the light absorbing film forming step S3 (see FIG. 12) and the shrinking step S4 (see FIG. 13) are executed by using the separating apparatus 70. However, the light absorbing film forming step S3 and the shrinking step S4 may be executed by a sheet treatment apparatus prepared separately from the separating apparatus 70. In this case, the sheet treatment apparatus includes the above-described light absorbing film forming unit 86 and light irradiation unit 92. Further, after the reinforcing portion 33 is separated from the object 11A by the separating apparatus 70, the non-fixed region 21a of the sheet 21 is heated by the sheet treatment apparatus, and loosening of the sheet 21 is suppressed.

Besides, structures, methods, and the like according to the present embodiment can be carried out with appropriate changes without departing from the scope of the object of the present invention. Moreover, the present embodiment can be combined with the first embodiment as appropriate, and the description of the first embodiment can be incorporated as appropriate concerning matters about which description is omitted in the present embodiment.

### Third Embodiment

In the above-described first embodiment, the description has been given of the manufacturing method for a chip in which the object 11 is divided into the plurality of chips 11d by expanding the sheet 21 (see FIG. 5B). However, H in manufacturing the chips 11d, the sheet 21 is sometimes expanded also at a timing other than the time of the dividing of the object 11. In the following, a description is given of a form in which the sheet 21 is expanded after the object 11 is divided into the plurality of chips 11d.

In the treatment method for a sheet (manufacturing method for a chip) according to the present embodiment, first, the object 11 is divided into the plurality of chips 11d in the treatment step S2 (dividing step). In the present embodiment, a dividing method for the object 11 different from the first embodiment is described.

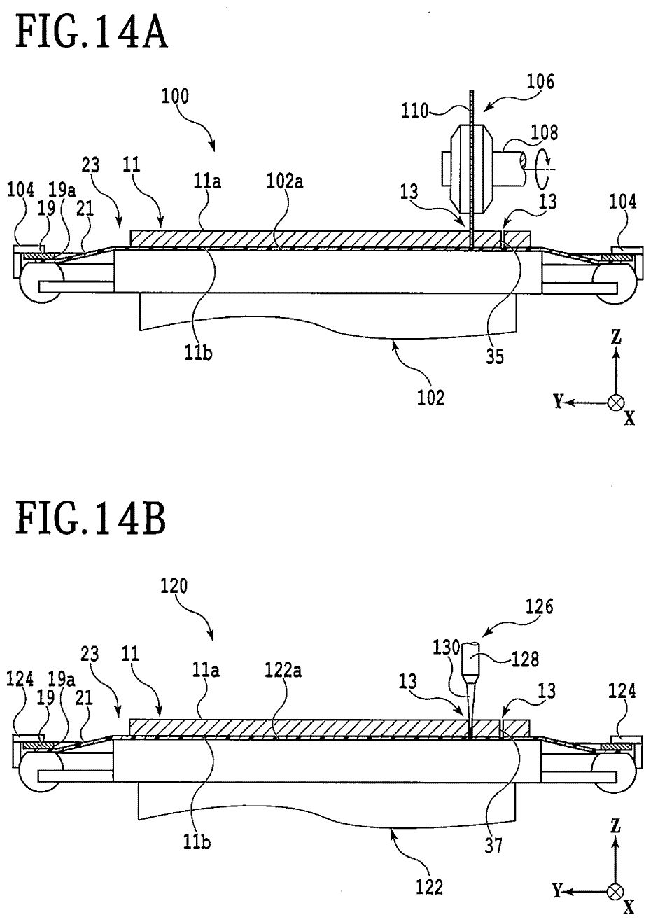

FIG. 14A is a sectional view depicting the object 11 divided by cutting processing. For example, in the dividing step, the object 11 may be divided by cutting the object 11 along the planned dividing lines 13 by an annular cutting blade. For example, a cutting apparatus 100 is used for the cutting processing for the object 11.

The cutting apparatus 100 includes a chuck table (holding table) 102 that holds the object 11. The upper surface of the chuck table 102 is a circular flat surface substantially parallel to a horizontal plane (XY-plane), and forms a holding surface 102a that holds the object 11. The holding surface 102a is connected to a suction source (not depicted) such as an ejector through a flow path (not depicted) formed inside the chuck table 102, a valve (not depicted), and the like.

A movement mechanism (not depicted) of a ball screw system that moves the chuck table 102 along the X-axis direction is coupled to the chuck table 102. Further, a rotational drive source (not depicted) such as a motor that rotates the chuck table 102 around a rotation axis substantially perpendicular to the holding surface 102a is coupled to the chuck table 102. Moreover, a plurality of clamps 104 that grasp and fix the frame 19 that supports the object 11 are disposed around the chuck table 102.

Further, the cutting apparatus 100 includes a cutting unit 106 that executes the cutting processing. The cutting unit 106 is set over the chuck table 102, and includes a circular columnar spindle 108 disposed along the Y-axis direction. An annular cutting blade 110 is mounted on a tip portion of the spindle 108. Moreover, a movement mechanism (not depicted) of a ball screw system that moves the cutting unit 106 along the Y-axis direction and the Z-axis direction is coupled to the cutting unit 106.

For example, a cutting blade of a hub type (hub blade) is used as the cutting blade 110. The hub blade includes an annular hub base composed of a metal such as an aluminum alloy and an annular cutting edge formed along the outer circumferential edge of the hub base. The cutting edge of the hub blade is formed of an electroformed abrasive stone containing abrasive grains composed of diamond, cubic boron nitride (cBN), or the like and a bond such as a nickel plating layer that fixes the abrasive grains. However, it is also possible to use a cutting blade of a washer type (washer blade) as the cutting blade 110. The washer blade is formed of only an annular cutting edge containing abrasive grains and a bond that is composed of a metal, ceramic, resin, or the like and fixes the abrasive grains.

In dividing the object 11 by the cutting apparatus 100, first, the object 11 is held by the chuck table 102. For example, the object 11 is disposed on the chuck table 102 such that the side of the front surface 11a is oriented upward and the side of the back surface 11b (side of the sheet 21) faces the holding surface 102a. Further, the frame 19 is fixed by the plurality of clamps 104. When a suction force (negative pressure) of the suction source is made to act on the holding surface 102a in this state, the object 11 is sucked and held by the chuck table 102 with the interposition of the sheet 21.

Next, the chuck table 102 rotates, and the angle of the chuck table 102 is adjusted such that the length direction of the predetermined planned dividing line 13 corresponds with the X-axis direction. Further, the position of the cutting unit 106 in the Y-axis direction is adjusted to position the cutting blade 110 on an extended line of the predetermined planned dividing line 13. Moreover, the height of the cutting unit 106 is adjusted to cause the lower end of the cutting blade 110 to be disposed on the lower side relative to the back surface 11b of the object 11 (upper surface of the sheet 21) and on the upper side relative to the holding surface 102a (lower surface of the sheet 21).

Then, the chuck table 102 is moved along the X-axis direction while the cutting blade 110 is rotated. Thereby, the chuck table 102 and the cutting blade 110 relatively move along the X-axis direction (processing feed), and the cutting blade 110 cuts the object 11 along the planned dividing line 13. As a result, a groove (cutting groove) 35 that reaches the back surface 11b of the object 11 from the front surface 11a is formed along the planned dividing line 13. Then, when the grooves 35 have been formed along all planned dividing lines 13, the object 11 is divided into the plurality of chips 11d.

FIG. 14B is a sectional view depicting the object 11 divided by laser processing. In the dividing step, the object 11 may be divided by executing irradiation with a laser beam along the planned dividing line 13. For example, a laser processing apparatus 120 is used for the laser processing for the object 11.

The laser processing apparatus 120 includes a chuck table (holding table) 122 that holds the object 11. The upper surface of the chuck table 122 is a circular flat surface substantially parallel to a horizontal plane (XY-plane), and forms a holding surface 122a that holds the object 11. The holding surface 122a is connected to a suction source (not depicted) such as an ejector through a flow path (not depicted) formed inside the chuck table 122, a valve (not depicted), and the like.

A movement mechanism (not depicted) of a ball screw system that moves the chuck table 122 along the X-axis direction and the Y-axis direction is coupled to the chuck table 122. Further, a rotational drive source (not depicted) such as a motor that rotates the chuck table 122 around a rotation axis substantially perpendicular to the holding surface 122a is coupled to the chuck table 122. Moreover, a plurality of clamps 124 that grasp and fix the frame 19 that supports the object 11 are disposed around the chuck table 122.

Further, the laser processing apparatus 120 includes a laser irradiation unit 126 that executes irradiation with a laser beam. The laser irradiation unit 126 includes a laser oscillator (not depicted) of a YAG laser, a YVO₄ laser, a YLF laser, or the like and a laser processing head 128 disposed over the chuck table 122.

An optical system that guides a laser beam 130 of pulse oscillation emitted from the laser oscillator to the object 11 is incorporated in the laser processing head 128. The optical system includes optical elements such as a collecting lens that focuses the laser beam 130. The laser beam 130 emitted from the laser oscillator is applied to the object 11 from the laser processing head 128 and is focused on a predetermined position. Then, predetermined laser processing is executed for the object 11 by the laser beam 130.

In dividing the object 11 by the laser processing apparatus 120, first, the object 11 is held by the chuck table 122. For example, the object 11 is disposed on the chuck table 122 such that the side of the front surface 11a is oriented upward and the side of the back surface 11b (side of the sheet 21) faces the holding surface 122a. Further, the frame 19 is fixed by the plurality of clamps 124. When a suction force (negative pressure) of the suction source is made to act on the holding surface 122a in this state, the object 11 is sucked and held by the chuck table 122 with the interposition of the sheet 21.

Next, the chuck table 122 rotates, and the angle of the chuck table 122 is adjusted such that the length direction of the predetermined planned dividing line 13 corresponds with the X-axis direction. Further, the position of the chuck table 122 in the Y-axis direction is adjusted such that a region to be irradiated with the laser beam 130 is positioned on an extended line of the predetermined planned dividing line 13. Moreover, the height position of the laser processing head 128 and the arrangement of the optical system are adjusted to position the focal point of the laser beam 130 at the same height position as the object 11.

Then, the chuck table 122 is moved along the X-axis direction while irradiation with the laser beam 130 from the laser processing head 128 is executed. Thereby, the chuck table 122 and the laser beam 130 relatively move along the processing feed direction at a predetermined processing feed rate. As a result, irradiation with the laser beam 130 is executed along the planned dividing line 13 from the side of the front surface 11a of the object 11.

Irradiation conditions of the laser beam 130 are set to cause ablation processing to be executed for the object 11. Specifically, the wavelength of the laser beam 130 is set to cause at least part of the laser beam 130 to be absorbed by the object 11. That is, the laser beam 130 has absorbability with respect to the object 11. Further, other irradiation conditions of the laser beam 130 are also set as appropriate to cause proper ablation processing to be executed for the object 11. For example, when the object 11 is a single-crystal silicon wafer, irradiation conditions of the laser beam 130 can be set as follows.
Wavelength: 355 nm
Average output power: 2 W
Repetition frequency: 200 kHz
Processing feed rate: 400 mm/s

When the object 11 is processed under the above-described processing conditions, ablation processing is executed along the planned dividing line 13 of the object 11, and a groove (laser-processed groove) 37 that reaches the back surface 11b of the object 11 from the front surface 11a is formed along the planned dividing line 13. Then, when the grooves 37 have been formed along all planned dividing lines 13, the object 11 is divided into the plurality of chips 11d. Incidentally, when it is difficult to form the groove 37 by one time of irradiation with the laser beam, irradiation with the laser beam 130 may be executed multiple times along each planned dividing line 13.

As described above, the object 11 is divided into the plurality of chips 11d in the dividing step. Thereafter, the sheet 21 fixed to the object 11 (plurality of chips 11d) is expanded (expanding step). The expansion of the sheet 21 may be executed by using a dedicated apparatus like the above-described expanding apparatus 20 (FIG. 5A), or may be manually executed by a worker. When the expanding step is executed, the interval between the plurality of chips 11d fixed to the sheet 21 widens, and a certain degree of gap or larger gap is ensured between adjacent chips 11d. This decreases the possibility of occurrence of a collision between the chips 11d in subsequent conveyance of the object 11, and damage to the chips 11d is prevented.

As described above, in the treatment step S2, the sheet 21 may be expanded after the object 11 is divided. However, if the sheet 21 is expanded, loosening occurs in the sheet 21 similarly to the case of giving an external force to the object 11 (see FIG. 5B). Thus, after the treatment step S2, the light absorbing film 25 is formed on the non-fixed region 21a of the sheet 21 (light absorbing film forming step S3, see FIG. 6). Thereafter, the non-fixed region 21a is heated to be shrunk by irradiating the light absorbing film 25 with the light 42 and causing the light absorbing film 25 to generate heat (shrinking step S4, FIG. 8).

As described above, in the treatment method for a sheet (manufacturing method for a chip) according to the present embodiment, after dividing of the object 11 and expansion of the sheet 21 are executed in the treatment step S2, the non-fixed region 21a of the sheet 21 is heated to be shrunk in the shrinking step S4. This reduces or eliminates loosening that has occurred in the non-fixed region 21a.

Details of the light absorbing film forming step S3 and the shrinking step S4 are as described in the first embodiment. The timing of the formation of the light absorbing film 25 can be changed as appropriate as long as the timing is before the shrinking step S4. For example, the light absorbing film forming step S3 may be executed after the preparation step S1 and before the treatment step S2. Further, loosening of the sheet 21 in the treatment step S2 may be suppressed in advance by executing the light absorbing film forming step S3 and the shrinking step S4 before execution of the treatment step S2.

Besides, structures, methods, and the like according to the present embodiment can be carried out with appropriate changes without departing from the scope of the object of the present invention. Moreover, the present embodiment can be combined with the first embodiment as appropriate, and the description of the first embodiment can be incorporated as appropriate concerning matters about which description is omitted in the present embodiment.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A treatment method for a sheet by which treatment for the sheet fixed to an object is executed, the treatment method comprising:
preparing the object to which the sheet is fixed;
forming a light absorbing film that absorbs light and generates heat on a non-fixed region that is not fixed to the object in the sheet; and
heating and shrinking the non-fixed region by irradiating the light absorbing film with the light and causing the light absorbing film to generate heat.

2. The treatment method for a sheet according to claim 1, wherein
the sheet is fixed to an annular frame having an opening in which the object is allowed to be disposed, and
the non-fixed region is an annular region exposed between the object and the frame.

3. The treatment method for a sheet according to claim 1, wherein
treatment for the object is executed, and
the non-fixed region in which loosening has occurred due to the treatment for the object is shrunk.

4. The treatment method for a sheet according to claim 3, wherein
the treatment for the object is treatment of dividing the object along a planned dividing line by expanding the sheet after forming an origin of dividing in the object along the planned dividing line.

5. The treatment method for a sheet according to claim 3, wherein
the object in which a recess portion is made at a central portion and an annular reinforcing portion that surrounds the recess portion is made at an outer circumferential portion and for which the sheet is fixed to the recess portion and the reinforcing portion is prepared, and
the treatment for the object is treatment of separating the reinforcing portion from the object.

6. A manufacturing method for a chip by which an object to which a sheet is fixed is divided to manufacture the chip, the manufacturing method comprising:
preparing the object to which the sheet is fixed;
dividing the object into a plurality of the chips along a planned dividing line by expanding the sheet after forming an origin of dividing in the object along the planned dividing line;
forming a light absorbing film that absorbs light and generates heat on a non-fixed region that is not fixed to the object in the sheet; and
heating and shrinking the non-fixed region by irradiating the light absorbing film with the light and causing the light absorbing film to generate heat.

7. A manufacturing method for a chip by which an object to which a sheet is fixed is divided to manufacture the chip, the manufacturing method comprising:
preparing the object to which the sheet is fixed;
widening an interval between a plurality of the chips by expanding the sheet after dividing the object into the plurality of the chips along a planned dividing line;
forming a light absorbing film that absorbs light and generates heat on a non-fixed region that is not fixed to the object in the sheet; and
heating and shrinking the non-fixed region by irradiating the light absorbing film with the light and causing the light absorbing film to generate heat.

8. A manufacturing method for a substrate by which an object to which a sheet is fixed is processed to manufacture the substrate, the manufacturing method comprising:
preparing the object in which a recess portion is made at a central portion and an annular reinforcing portion that surrounds the recess portion is made at an outer circumferential portion and for which the sheet is fixed to the recess portion and the reinforcing portion;
separating the reinforcing portion from the object to manufacture the substrate;
forming a light absorbing film that absorbs light and generates heat on a non-fixed region that is not fixed to the object in the sheet; and
heating and shrinking the non-fixed region by irradiating the light absorbing film with the light and causing the light absorbing film to generate heat.
